(19) United States
(12) Patent Application Publication
(10) Pub. No.: US 2025/0309077 A1
(43) Pub. Date: Oct. 2, 2025

(54) SUBSTRATE WITH EMBEDDED ELECTRONIC COMPONENT AND METHOD OF MAKING THE SAME

(71) Applicant: SHINKO ELECTRIC INDUSTRIES CO., LTD., Nagano (JP)

(72) Inventors: Shinichiro SEKIJIMA, Nagano (JP); Masataka KAZAMA, Nagano (JP); Satoshi MATSUZAWA, Nagano (JP); Kenkichi ARAI, Nagano (JP)

(21) Appl. No.: 19/088,100

(22) Filed: Mar. 24, 2025

(30) Foreign Application Priority Data
Mar. 28, 2024 (JP) 2024-053405

(51) Int. Cl. H01L 23/498; H01L 21/48; H01L 23/31

(52) U.S. Cl. CPC H01L 23/49816; H01L 21/4853; H01L 23/3135; H01L 23/49833

(57) ABSTRACT

A substrate with an embedded electronic component includes a first substrate, a second substrate on which an electronic component is mounted, a substrate connecting member electrically connecting a first pad of the first substrate and a second pad of the second substrate, an encapsulating resin filling a gap between the first substrate and the second substrate to cover the electronic component, wherein the first substrate is disposed opposite the second substrate across the electronic component, wherein a surface area of the second pad in contact with the substrate connecting member is larger than a surface area of the first pad in contact with the substrate connecting member, and wherein the substrate connecting member includes a first section whose width gradually narrows from a surface of the second pad toward a position between the first pad and a center of the substrate connecting member in a height direction in cross-sectional view.

### CROSS-REFERENCE TO RELATED APPLICATIONS

The present application is based on and claims priority to Japanese Patent Application No. 2024-053405 filed on Mar. 28, 2024, with the Japanese Patent Office, the entire contents of which are incorporated herein by reference.

### FIELD

The disclosures herein relate to substrates with an embedded electronic component and methods of manufacturing such a substrate.

### BACKGROUND

A substrate with an embedded electronic component as known in the art may include a first substrate, a second substrate facing the first substrate, substrate connecting members interposed between the first substrate and the second substrate to transmit signals between the first substrate and the second substrate, and an encapsulating resin for encapsulating the gap between the first substrate and the second substrate with the substrate connecting members intervening therebetween, with an electronic component such as a semiconductor chip mounted on the second substrate (See, for example, Patent Document 1).

With respect to the substrate with an embedded electronic component as described above, it is preferable to secure a predetermined gap between the opposing surfaces of the electronic component and the first substrate and then fill the gap with an encapsulating resin.

There may thus be a need for a method of making a substrate with an embedded electronic component, which enables the gap between opposing surfaces of the electronic component and the first substrate to be easily filled with an encapsulating resin.

### PRIOR ART DOCUMENTS

### Patent Documents

[Patent Document 1] International Publication Pamphlet No. WO2007/069606

### SUMMARY

According to an aspect of the embodiment, a substrate with an embedded electronic component includes a first substrate, a second substrate on which an electronic component is mounted, a substrate connecting member electrically connecting a first pad of the first substrate and a second pad of the second substrate, an encapsulating resin filling a gap between the first substrate and the second substrate to cover the electronic component, wherein the first substrate is disposed opposite the second substrate across the electronic component, wherein a surface area that is part of the second pad and that is in contact with the substrate connecting member is larger than a surface area that is part of the first pad and in contact with the substrate connecting member, and wherein the substrate connecting member includes a first section whose width gradually narrows from a surface of the second pad toward a position between the first pad and a center of the substrate connecting member in a height direction in cross-sectional view.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are cross-sectional views illustrating an example of a substrate with an embedded electronic component according to a first embodiment;

FIGS. 2A through 2C are drawings illustrating an example of a manufacturing process of the substrate with an embedded electronic component according to the first embodiment; and

FIGS. 3A through 3C are drawings illustrating the example of the manufacturing process of the substrate with an embedded electronic component according to the first embodiment.

### DESCRIPTION OF EMBODIMENTS

In the following, an embodiment for carrying out the invention will be described with reference to the accompanying drawings. In each of the drawings, the same components are referred to by the same reference numerals, and duplicate descriptions may be omitted.

### First Embodiment

[Structure of Substrate with Embedded Electronic Component]

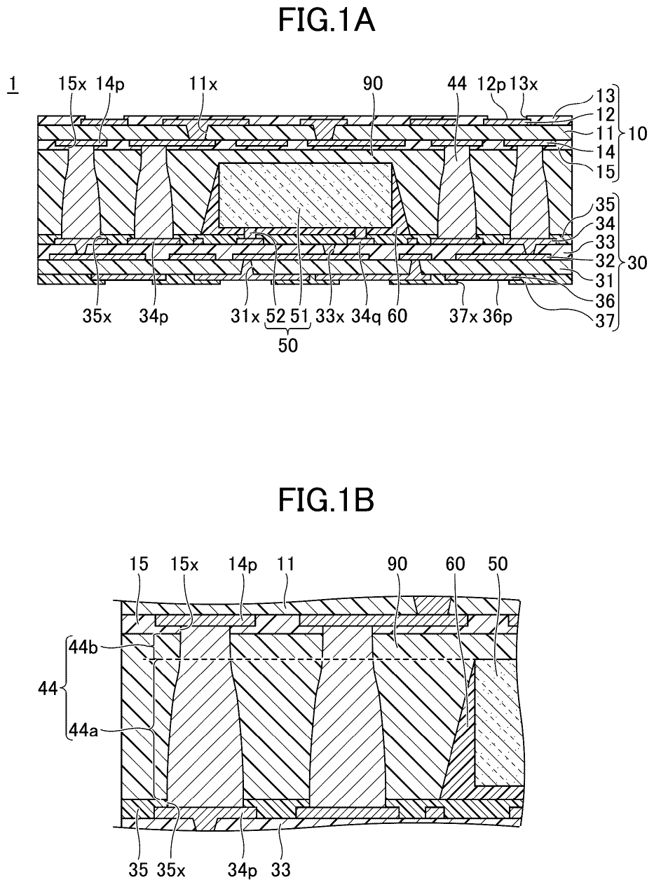

FIGS. 1A and 1B are cross-sectional views illustrating an example of a substrate with an embedded electronic component according to a first embodiment. FIG. 1A is an overall view, and FIG. 1B is a partial enlarged view of substrate connecting members and their surroundings illustrated in FIG. 1A.

Referring to FIGS. 1A and 1B, a substrate 1 with an embedded electronic component includes a first substrate 10, a second substrate 30, substrate connecting members 44, a semiconductor chip 50, and an encapsulating resin 90. In the substrate 1 with an embedded electronic component, the semiconductor chip 50 is mounted on the second substrate 30, and the first substrate 10 is arranged opposite the second substrate 30 across the semiconductor chip 50. The encapsulating resin 90 fills the gap between the first substrate 10 and the second substrate 30 to cover the semiconductor chip 50.

In the present embodiment, for the sake of convenience, the solder resist layer 13 side of the substrate 1 with an embedded electronic component in FIG. 1A is referred to as an upper side or a first side, and the solder resist layer 37 side is referred to as a lower side or a second side. In addition, the surface of an object oriented in the same direction as the solder resist layer 13 side is referred to as a first surface or an upper surface, and the surface of the object oriented in the same direction as the solder resist layer 37 side is referred to as a second surface or a lower surface. However, the substrate 1 with an embedded electronic component may be used upside down or may be arranged at any angle. The plan view refers to the view of an object as seen from the direction normal to the first surface of the solder resist layer 13, and the plane shape refers to the shape of an object as seen from the direction normal to the first surface of the solder resist layer 13. When the substrate 1 with an embedded electronic component is illustrated upside down relative to FIG. 1A, the definition of the upper side and the lower side becomes opposite to that described above, in accordance with the orientation of the drawing.

The substrate first 10 includes an layer 12, a insulating layer 11, an interconnect solder resist layer 13, an interconnect layer 14, and a solder resist layer 15.

In the first substrate 10, the insulating layer 11 may be, for example, a glass epoxy substrate or the like in which an insulating resin, such as epoxy-based resin, is impregnated into a glass cloth. The insulating layer 11 may be a substrate or the like in which an insulating resin, such as epoxy-based resin, is impregnated into a woven fabric or a nonwoven fabric such as a glass fiber, carbon fiber or aramid fiber. The thickness of the insulating layer 11 may be, for example, about 60 to 200 μm. The illustration of the glass cloth or the like is omitted in each of the drawings.

The interconnect layer 12 is formed on the first side of the insulating layer 11. The interconnect layer 12 is electrically connected to the interconnect layer 14 through the insulating layer 11. The interconnect layer 12 includes at least one via interconnect filling a via hole 11x penetrating the insulating layer 11 and reaching the first surface of the interconnect layer 14, and also includes an interconnect pattern formed on the first surface of the insulating layer 11.

The via hole 11x is an inverted truncated conical recess in which the diameter of an opening towards the solder resist layer 13 is larger than the surface formed by the upper diameter of a bottom surface of the interconnect layer 14. The diameter of the opening of the via hole 11x may be, for example, about 50 μm. The material of the interconnect layer 12 may be, for example, copper (Cu) or the like. The thickness of the interconnect pattern of the interconnect layer 12 may be, for example, about 10 to 20 μm.

The solder resist layer 13 is formed on the first surface of the insulating layer 11 so as to cover the interconnect layer 12. The solder resist layer 13 may be, for example, made of photosensitive resin or the like. The thickness of the solder resist layer 13 may be, for example, about 15 to 35 μm. The solder resist layer 13 has at least one opening 13x, and a part of the interconnect layer 12 is exposed in the opening 13x. The interconnect layer 12 exposed in the opening 13x forms a pad 12p. The pad 12p serves to establish an electrical connection to an electronic component (not shown) such as a semiconductor chip or a semiconductor package.

The solder resist layer 13 may be configured to completely expose the pad 12p. In this case, the solder resist layer 13 may be provided so that the side surface of the pad 12p is in contact with the inner wall surface of the opening 13x, or the solder resist layer 13 may be provided so that there is a gap between the side surface of the pad 12p and the inner wall surface of the opening 13x.

According to need, a metal layer may be formed on the first surface of the pad 12p, or an antioxidation treatment such as OSP (organic solderability preservative) treatment may be applied. Examples of the metal layer include an Au layer, a Ni/Au layer (i.e., a metal layer made by laminating a Ni layer and an Au layer in this order), and a Ni/Pd/Au layer (i.e., a metal layer made by laminating a Ni layer, a Pd layer, and an Au layer in this order). An external connection terminal such as a solder ball may be formed on the first surface of the pad 12p. The interconnect layer 14 is formed on the second surface of the insulating layer 11. The interconnect layer 14 includes, for example, a pad and an interconnect pattern provided on the same surface as the pad. The first surface of the interconnect layer 14 is in contact with, and electrically connected to, the lower end of the via interconnect of the interconnect layer 12 filling the via hole 11x. The material and thickness of the interconnect layer 14 may be, for example, substantially the same as those of the interconnect pattern of the interconnect layer 12.

The solder resist layer 15 is formed on the second surface of the insulating layer 11 so as to cover the interconnect layer 14. The material and thickness of the solder resist layer 15 may be, for example, substantially the same as those of the solder resist layer 13. The solder resist layer 15 has an opening 15x, and a part of the interconnect layer 14 is located in the opening 15x. The plane shape of the opening 15x may be, for example, circular. The interconnect layer 14 situated in the opening 15x constitutes a pad 14p. The pad 14p serves to establish an electrical connection to a substrate connecting member 44. If necessary, the second surface of the pad 14p may have the previously described metal layer formed thereon, or subjected to antioxidation treatment such as OSP treatment.

The second substrate 30 includes an insulating layer 31, an interconnect layer 32, an insulating layer 33, an interconnect layer 34, a solder resist layer 35, an interconnect layer 36, and a solder resist layer 37.

In the second substrate 30, the material and thickness of the insulating layer 31 may be substantially the same as those of the insulating layer 11, for example. The interconnect layer 32 is formed on the first surface of the insulating layer 31. The material and thickness of the interconnect layer 32 may be the same as those of the interconnect pattern of the interconnect layer 12, for example.

The insulating layer 33 is formed on the first surface of the insulating layer 31 so as to cover the interconnect layer 32. An insulating resin, such as a thermosetting epoxy-based resin, may be used as the material of the insulating layer 33. The insulating layer 33 may contain a filler such as silica (SiO₂). The thickness of the insulating layer 33 may be, for example, about 15 to 35 μm.

The interconnect layer 34 is formed on the first side of the insulating layer 33. The interconnect layer 34 includes at least one via interconnect filling a via hole 33x penetrating the insulating layer 33 and reaching the first surface of the interconnect layer 32, and also includes an interconnect pattern formed on the first surface of the insulating layer 33. The interconnect pattern of the second substrate 30 on which the semiconductor chip 50 is mounted is denser than the interconnect pattern of the first substrate 10.

The via hole 33x is an inverted truncated conical recess which has an opening toward the solder resist layer 35 and a bottom surface formed by the first surface of the interconnect layer 32, and the area of the opening is larger than the area of the bottom surface. The material of the interconnect layer 34 and the thickness of the interconnect pattern of the interconnect layer 34 may be, for example, the same as those of the interconnect layer 12.

The solder resist layer 35 is a protective insulating layer formed on the first surface of the insulating layer 33 so as to cover the interconnect layer 34. The material and thickness of the solder resist layer 35 may be substantially the same as those of the solder resist layer 13, for example. The solder resist layer 35 has at least one opening 35x, and a part of the interconnect layer 34 is located in the opening 35x. The plane shape of the opening 35x may be circular, for example. The interconnect layer 34 situated in the opening 35x serves as pads 34p and 34q. In plan view, the size of the opening 35x may be larger than the opening 15x or smaller than the opening 15x.

The pad 34p serves to establish a connection to a substrate connecting member 44. The pad 34q serves to establish a connection to an electrode 52 of the semiconductor chip 50. A plurality of pads 34p and a plurality of pads 34q are formed on the semiconductor chip 50 side of the second substrate 30. The pads 34q and electrodes 52 may be connected to each other via a conductive bonding material, for example. The conductive bonding material may be a solder material such as an alloy containing Pb, an alloy of Sn and Cu, an alloy of Sn and Sb, an alloy of Sn and Ag, or an alloy of Sn, Ag, and Cu.

The aperture diameters of the pads 34p electrically connected to the substrate connecting members 44 and the pads 34q electrically connected to the semiconductor chip 50 may be set independently of each other. According to need, the first surfaces of the pads 34p and 34q may have the previously described metal layer formed thereon, or may be subjected to an antioxidation treatment such as OSP treatment.

The interconnect layer 36 is formed on the second side of the insulating layer 31. The interconnect layer 36 includes at least one via interconnect filling a via hole 31x penetrating the insulating layer 31 and extending to the second surface of the interconnect layer 32, and also includes an interconnect pattern formed on the second surface of the insulating layer 31.

The via hole 31x is a truncated conical recess which has an opening toward the solder resist layer 37 and an end surface formed by the second surface of the interconnect layer 32, and the area of the opening is larger than the area of the bottom surface. The upper end of the via interconnect of the interconnect layer 36 filling the via hole 31x is in contact with, and electrically connected to, the second surface of the interconnect layer 32. The material of the interconnect layer 36 and the thickness of the interconnect pattern of the layer 36 may interconnect be, for example, substantially the same as those of the interconnect layer 12.

The solder resist layer 37 is formed on the second surface of the insulating layer 11 so as to cover the interconnect layer 36. The material and the thickness of the solder resist layer 37 may be, for example, substantially the same as those of the solder resist layer 13. The solder resist layer 37 has at least one opening 37x, and a part of the interconnect layer 36 is exposed in the opening 37x. The interconnect layer 36 exposed in the opening 37x forms a pad 36p. The pad 36p serves to establish an electrical connection to a mounting substrate such as a motherboard. An external connection terminal such as a solder ball may be formed on the second surface of the pad 36p. If necessary, the second surface of the pad 36p may have the previously discussed metal layer formed thereon, or may be subjected to an antioxidation treatment such as OSP treatment.

The semiconductor chip 50 is flip-chip mounted face-down on the first surface of the second substrate 30 (i.e., with the circuit surface facing the first surface of the second substrate 30). More specifically, the semiconductor chip 50 includes a chip core 51, having a semiconductor integrated circuit, and electrodes 52 as connection terminals, and the electrodes 52 of the semiconductor chip 50 are electrically connected to the pads 34q of the second substrate 30. The electrodes 52 may be, for example, gold bumps, solder bumps, or copper posts with solder at their tips.

It may be noted that an electronic component incorporated in the substrate 1 with an embedded electronic component is not limited to a semiconductor chip. Instead of a semiconductor chip, passive elements such as capacitors, inductors, and resistors may be embedded. Alternatively, a CSP (chip size package) in which a semiconductor chip is provided with a redistribution layer may be embedded in the semiconductor chip. Alternatively, these components may be present in a mixture.

It is preferable to inject an underfill resin 60 into a gap between the semiconductor chip 50 and the second substrate 30 for improved reliability. The underfill resin 60 may cover part or all of the side surfaces of the semiconductor chip 50. The underfill resin 60 does not cover the upper surface of the semiconductor chip 50.

The substrate connecting members 44 are disposed between the pads 14p of the first substrate 10 and the pads 34p of the second substrate 30 to electrically connect the pads 14p and 34p. The substrate connecting members 44 have the function to secure a predetermined distance between the first substrate 10 and the second substrate 30. The surface area of the pad 34p that is in contact with the substrate connecting member 44 is larger than the surface area of the pad 14p that is in contact with the substrate connecting member 44. The surface area of the pad 34p that is in contact with the substrate connecting member 44 refers to the area of the surface of the pad 34p located within the opening 35x. The surface area of the pad 14p that is in contact with the substrate connecting member 44 refers to the area of the surface of the pad 14p located within the opening 15x. In cross-sectional view, the surface portion of the pad 14p that is in contact with the substrate connecting member 44 may have a width of, for example, about 110 to 150 μm. In cross-sectional view, the surface portion of the pad 34p that is in contact with the substrate connecting member 44 may have a width of, for example, about 140 to 180 μm.

The substrate connecting members 44 may be formed of a solder material such as an alloy containing Pb, an alloy of Sn and Cu, an alloy of Sn and Sb, an alloy of Sn and Ag, or an alloy of Sn, Ag, and Cu. The substrate connecting members 44 may include a metal core made of a metal such as copper, a resin core made of resin, or the like. These cores are coated with a solder material.

The substrate connecting members 44 may be arranged around the semiconductor chip 50 in a peripheral pattern in plan view, for example. For example, when the maximum width of the substrate connecting members 44 is about 150 μm in cross-sectional view, the pitch of the substrate connecting members 44 may be about 200 μm.

In cross-sectional view, the substrate connecting member 44 has a first section 44a whose width gradually narrows from the surface of the pad 34p toward a position between the pad 14p and the center of the substrate connecting member 44 in the height direction. The first section 44a has a substantially trapezoidal shape in cross-sectional view, for example. The parts of the first section 44a that form the legs of the trapezoid in cross-sectional view may be linear, curved, or a mixture of these.

In cross-sectional view, the substrate connecting member 44 may have a second section 44b having a constant width between the pad 14p and the first section 44a. The term “constant width” includes a case where the difference between the maximum width and the minimum width is 3 μm or less. As measured from the surface of the pad 34p, the height of the boundary between the first section 44a and the second section 44b is the same as the height of the surface of the semiconductor chip 50 on the pad 14p side, as illustrated by the dashed line in FIG. 1B. The term “same” includes a case where the difference in height between the two is 10 μm or less.

Since the substrate connecting member 44 has the first section 44a, the width of the substrate connecting member is narrower on the side closer to the pad 14p in cross-sectional view. During the process of forming the encapsulating resin 90 in the manufacturing process of the substrate 1 with an embedded electronic component, this arrangement effectively improves the fluidity of the encapsulating resin 90 around the portion of the substrate connecting member 44 closer to the pad 14p. As a result, the encapsulating resin 90 may easily fill the gap between the opposing surfaces of the semiconductor chip 50 and the first substrate 10. Further, this arrangement effectively reduces the possibility of voids occurring between the opposing surfaces of the semiconductor chip 50 and the first substrate 10.

The substrate connecting member 44 has an elongated shape with its longitudinal direction being along the thickness direction of the substrate 1 with an embedded electronic component. This arrangement allows the pitch between the adjacent substrate connecting members 44 to be narrow, thereby reducing the widthwise size of the substrate 1 with an embedded electronic component. For example, if substrate connecting members approximately circular in cross-sectional view were used with the distance between the first substrate 10 and the second substrate 30 being the same as in FIG. 1A, the pitch between the adjacent substrate connecting members could not be narrow, causing the substrate with an embedded electronic component to become larger in the width direction. Such a problem may be avoided by using the substrate connecting members 44 having the shape illustrated in the figure. This effect is particularly prominent when an increase in the thickness of the semiconductor chip 50 causes the distance between the first substrate 10 and the second substrate 30 to be increased.

The encapsulating resin 90 fills the gap between the opposing surfaces of the first substrate 10 and the second substrate 30 to cover the substrate connecting members 44 and the semiconductor chip 50. The encapsulating resin 90 also fills the gap between the opposing surfaces of the semiconductor chip 50 and the first substrate 10. For example, an insulating resin such as a thermosetting epoxy-based resin containing a filler may be used as the encapsulating resin 90.

[Method of Making Substrate with Embedded Electronic Component]

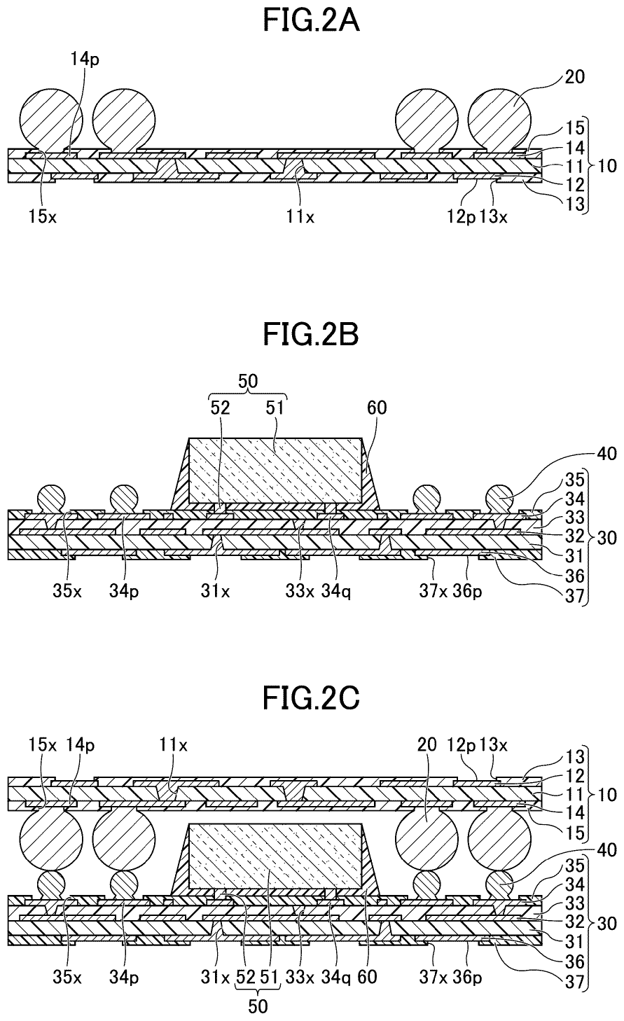

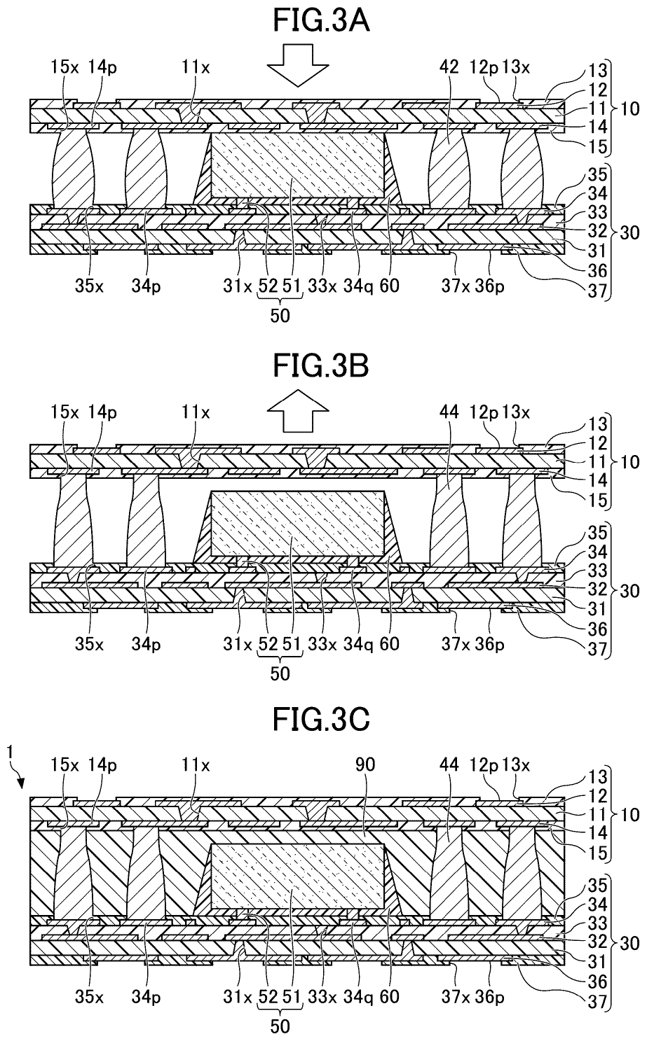

FIGS. 2A through 2C and FIGS. 3A through 3C are drawings illustrating an example of the manufacturing process of the substrate with an embedded electronic component according to the first embodiment.

First, in the step illustrated in FIG. 2A, the first substrate 10 is fabricated, and substrate connecting members 20 in contact with the pads 14p are mounted on the first substrate 10. Specifically, the insulating layer 11 made of a glass epoxy substrate or the like is prepared, and the interconnect layer 14 is formed on the second surface of the insulating layer 11. Then, the via holes 11x exposing the first surface of the interconnect layer 14 are formed through the insulating layer 11, and the interconnect layer 12 is formed on the first surface of the insulating layer 11. The interconnect layer 12 and the interconnect layer 14 are electrically connected across the insulating layer 11.

After the via holes 11x are formed, desmearing is preferably performed to remove resin residue adhered to the surface of the interconnect layer 14 exposed at the end of the via holes 11x. The via holes 11x may be formed by a laser processing method using, for example, a CO₂ laser. The interconnect layers 12 and 14 may be formed by one of various interconnect forming methods such as a semi-additive method or a subtractive method. For example, the interconnect layers 12 and 14 may be formed by copper plating or the like.

Subsequently, the solder resist layer 13 covering the interconnect layer 12 is formed on the first surface of the insulating layer 11, and the solder resist layer 15 covering the interconnect layer 14 is formed on the second surface of the insulating layer 11. The solder resist layer 13 may be formed by applying, for example, an insulating resin such as a photosensitive epoxy-based resin in liquid or paste form to the first surface of the insulating layer 11 by a screen printing method, a roll coating method, or a spin coating method so as to cover the interconnect layer 12.

Similarly, the solder resist layer 15 may be formed by applying, for example, an insulating resin such as a photosensitive epoxy-based resin in liquid or paste form to the second surface of the insulating layer 11 by a similar method so as to cover the interconnect layer 14. Alternatively, instead of applying the resin liquid or paste, an insulating resin such as a photosensitive epoxy-based resin film may be laminated.

By exposing and developing the coated or laminated insulating resin, the openings 13x and 15x are formed in the solder resist layers 13 and 15, respectively, thereby forming the pads 12p and 14p. This completes the first substrate 10 in its final form. The openings 13x and 15x may be formed by laser processing or blast processing. The plane shapes of the openings 13x and 15x may be, for example, circular. The diameters of the openings 13x and 15x may be determined as appropriate according to the object that is to be connected.

Thereafter, the substrate connecting members 20 are placed on the surface of the pads 14p exposed in the openings 15x of the solder resist layer 15 of the first substrate 10. Heating to a predetermined temperature melts the surface of the substrate connecting members 20, which is then solidified and joined to the pads 14p. The substrate connecting members 20 may be arranged in a peripheral pattern, for example.

As the substrate connecting members 20, for example, solder balls without cores may be used. The diameter of the substrate connecting members 20 may be, for example, about 150 μm to 350 μm. The material of the substrate connecting members 20 may be a solder material such as an alloy containing Pb, an alloy of Sn and Cu, an alloy of Sn and Sb, an alloy of Sn and Ag, or an alloy of Sn, Ag, and Cu. The substrate connecting members 20 may alternatively be solder balls with cores, each of which includes a spherical core and a conductive member covering g the outer surface of the core. As the core, for example, a metal core made of a metal such as copper or a resin core made of resin may be used. The conductive member may be made of, for example, the solder material described above. The diameter of the core is smaller than the thickness of the semiconductor chip 50.

Next, in the step illustrated in FIG. 2B, the second substrate 30 is fabricated, and substrate connecting members 40 in contact with the pads 34p are mounted on the second substrate 30. The semiconductor chip 50 is also mounted on the pads 34q of the second substrate 30. The second substrate 30 may be manufactured, for example, by repeating the steps of making the first substrate 10 as appropriate. The substrate connecting members 40 may be mounted in the same manner as the substrate connecting members 20. Like the substrate connecting members 20, the substrate connecting members 40 may be solder balls without cores or solder balls with cores. The diameter of the core is smaller than the thickness of the semiconductor chip 50. More specifically, the diameter of the core is smaller than the total thickness of the semiconductor chip 50 and the electrodes 52, or is smaller than the distance from the electronic-component mounting surface of the second substrate 30 to the surface of the semiconductor chip 50 oriented toward the first substrate 10.

The substrate connecting members 20 and 40 are spherical. Although the diameters of the substrate connecting members 20 and the substrate connecting members 40 may be the same or different, the diameter of the substrate connecting members 40 is preferably smaller than the diameter of the substrate connecting members 20. By making the diameter of the substrate connecting members 40 mounted on the second substrate 30 smaller than the diameter of the substrate connecting members 20, the substrate connecting members 44 formed in the subsequent process are unlikely to become wider on the side closer to the second substrate 30. The possibility of short-circuiting between the adjacent substrate connecting members 44 may thus be reduced. Such an effect is particularly prominent when the interconnect pattern of the second substrate 30 on which the semiconductor chip 50 is mounted has a higher density than the interconnect pattern of the first substrate 10.

The semiconductor chip 50 is mounted on the second substrate 30 such that the electrodes 52 provided on the lower surface of the chip core 51 are joined to the pads 34q. Specifically, a conductive bonding material such as solder paste is applied to the pads 34q of the second substrate 30. After the semiconductor chip 50 is prepared, the back surface of the semiconductor chip 50, for example, is mounted on the lower surface of a pickup jig. The pickup jig with the semiconductor chip 50 mounted on the lower surface is moved to a position directly above the second substrate 30, and the electrodes 52 of the semiconductor chip 50 are aligned with the conductive bonding materials. The semiconductor chip 50 is then placed on the second substrate 30. After the pickup jig is removed from the semiconductor chip 50, the conductive bonding material is heated and melted by reflow soldering, and then solidified. With this arrangement, the electrodes 52 of the semiconductor chip 50 are electrically connected to the pads 34q of the second substrate 30 via the conductive bonding material. After that, the underfill resin 60 preferably fills the gap between the semiconductor chip 50 and the second substrate 30 for improved reliability.

In the step illustrated in FIG. 2C, the first substrate 10 on which the substrate connecting members 20 are mounted in the step illustrated in FIG. 2A is prepared with the second substrate 30 on which the substrate connecting members 40 and the semiconductor chip 50 mounted are in the step illustrated in FIG. 2B. The first substrate 10 is stacked on the second substrate 30 such that the substrate connecting members 20 are brought in contact with the respective substrate connecting members 40.

Specifically, a first mold and a second mold positioned above the first mold at a predetermined interval are prepared. Then, the second substrate 30 is held on the upper side of the first mold, and the first substrate 10 is held on the lower side of the second mold. The second mold is lowered toward the first mold until the substrate connecting members 20 mounted on the first substrate 10 contact the respective substrate connecting members 40 mounted on the second substrate 30, which results in the first substrate 10 being stacked on the second substrate 30. As illustrated in the drawing, the total height of the substrate connecting members 20 and the substrate connecting members 40 is greater than the distance from the surface of the second substrate 30 to the surface of the semiconductor chip 50 on the side toward the first substrate 10.

In the step illustrated in FIG. 3A, while heating the first substrate 10 and the second substrate 30, the first substrate 10 is further moved toward the substrate second 30 until the first substrate 10 and the semiconductor chip 50 come into contact with each other. The substrate connecting members 20 and 40 are melted to form consolidated substrate connecting members 42.

Specifically, for example, while heating the first mold and the second mold with a heater to melt the substrate connecting members 20 and 40, the second mold is lowered toward the first mold until the solder resist layer 15 of the first substrate 10 contacts the semiconductor chip 50. The first substrate 10 is pressed toward the second substrate 30. As a result, heat from the second mold is transmitted to the substrate connecting members 20 via the first substrate 10, and heat from the first mold is transmitted to the substrate connecting members 40 via the second substrate 30. The substrate connecting members 20 and 40 are melted and combined to form the substrate connecting members 42 having a substantially elliptical shape in cross-sectional view. The heating temperature by the heater may be higher than the temperature at which the substrate connecting members 20 and 40 melt, and may be, for example, about 250° C.

In the step illustrated in FIG. 3B, the first substrate 10 is moved away from the second substrate 30 to form a gap between the first substrate 10 and the semiconductor chip 50, and the substrate connecting members 44 are formed by solidifying the substrate connecting members 42. The substrate connecting members 42 in the heated and melted state are deformed into a more elongated shape by the movement of the first substrate 10, resulting in the formation of the substrate connecting members 44. In cross-sectional view, the maximum width of the substrate connecting members 44 is narrower than the maximum width of the substrate connecting members 42. Also, the height of the substrate connecting members 44 is higher than the height the substrate connecting members 42.

Specifically, for example, the second mold holding the first substrate 10 is moved upward to form a gap between the solder resist layer 15 of the first substrate 10 and the semiconductor chip 50. During this process, the upper portions of the molten substrate connecting members 42 are pulled and extended by the movement of the first substrate 10, so that the substrate connecting members 44 have a different shape than the substrate connecting members 42. As illustrated in the drawing, the surface area of the pad 34p that is in contact with the substrate connecting member 44 is larger than the surface area of the pad 14p that is in contact with the substrate connecting member 44.

Consequently, as illustrated in FIG. 1B, the substrate connecting members 44 each have the first section 44a whose width gradually narrows from the surface of the pad 34p toward a position between the pad 14p and the center of the substrate connecting member 44 in the height direction, and the second section 44b whose width is constant between the pad 14p and the first section 44a. In this state, heating of the first mold and the second mold is stopped, solidifying the substrate connecting members 44. With this arrangement, the upper sides of the substrate connecting members 44 are joined to the pads 14p of the first substrate 10, and the lower sides are joined to the pads 34p of the second substrate 30. That is, the first substrate 10 and the second substrate 30 are electrically connected via the substrate connecting members 44.

Subsequently, in the step illustrated in FIG. 3C, the encapsulating resin 90 is formed to fill the gap between the first substrate 10 and the second substrate 30 and cover the semiconductor chip 50. As the encapsulating resin 90, for example, an insulating resin such as a thermosetting epoxy-based resin containing a filler may be used. The encapsulating resin 90 may be formed by, for example, a transfer molding method using a sealing mold.

Through the above-described steps, the substrate 1 with an embedded electronic component is effectively constructed. If necessary, external connection terminals such as solder balls may be formed on the pads 36p.

As described above, during the manufacture of the substrate 1 with an embedded electronic the component, the first substrate 10 and semiconductor chip 50 are brought into contact with each other in the step illustrated in FIG. 3A. With this position being used as a reference, the first substrate 10 is then moved away from the second substrate 30 in the step illustrated in FIG. 3B. This enables the accurate securing of a gap between the opposing surfaces of the semiconductor chip 50 and the first substrate 10. That is, a gap with the and necessary sufficient size, allowing the encapsulating resin 90 injected in the subsequent step to enter, may be provided between the opposing surfaces of the semiconductor chip 50 and the first substrate 10. As a result, the encapsulating resin 90 may easily fill the gap between the opposing surfaces of the semiconductor chip 50 and the first substrate 10.

In addition, as described above, the width of each substrate connecting member 44 is narrower at the side closer to the pad 14p, which improves the fluidity of the encapsulating resin 90 around the portion of the substrate connecting member 44 close to the pad 14p. As a result, the encapsulating resin 90 reliably fills the gap between the opposing surfaces of the semiconductor chip 50 and the first substrate 10. Further, the possibility of voids occurring between the opposing of surfaces the semiconductor chip 50 and the first substrate 10 is effectively reduced.

Although the preferred embodiments have been described in detail above, the disclosed technology is not limited to the above-described and various modifications and embodiments, substitutions may be made to the above-described embodiments without departing from the scope of the claims.

For example, the first substrate or the second substrate may be a build-up substrate or the like having a larger number of interconnect layers and insulating layers. In this case, a coreless build-up substrate or a build-up substrate with a core may be used. In addition, a lead frame may be used as the first substrate.

According to at least one embodiment, a method of making a substrate with an embedded electronic component is provided that enables a gap between the opposing surfaces of the electronic component and a first substrate to be easily filled with an encapsulating resin.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A method of making a substrate with an embedded electronic component, comprising:
mounting, on a first substrate having a first pad, a first substrate connecting member in contact with the first pad;
mounting, on a second substrate having a second pad, an electronic component and a second substrate connecting member that is in contact with the second pad;
stacking the first substrate on the second substrate such that the first substrate connecting member and the second substrate connecting member are brought into contact with each other;
moving the first substrate toward the second substrate while heating the first substrate and the second substrate until the first substrate and the electronic component come into contact with each other, thereby forming a third substrate connecting member made by melting and consolidating the first substrate connecting member and the second substrate connecting member;
moving the first substrate away from the second substrate to form a gap between the first substrate and the electronic component, and, in conjunction therewith, forming a fourth substrate connecting member made by solidifying the third substrate connecting member; and
forming an encapsulating resin filling a gap between the first substrate and the second substrate to cover the electronic component.

2. The method according to claim 1, wherein a sum of a height of the first substrate connecting member and a height of the second substrate connecting member is greater than a distance from a surface of the second substrate to a surface of the electronic component oriented toward the first substrate.

3. The method according to claim 1, wherein the first substrate connecting member and the second substrate connecting member are each spherical, and a diameter of the second substrate connecting member is smaller than a diameter of the first substrate connecting member.

4. The method according to claim 1, wherein the first substrate has a first interconnect pattern on a same plane as the first pad, and the second substrate has a second interconnect pattern on a same plane as the second pad, and
wherein the second interconnect pattern has a higher density than the first interconnect pattern.

5. The method according to claim 1, wherein a surface area that is part of the second pad and in contact with the fourth substrate connecting member is larger than a surface area that is part of the first pad and in contact with the fourth substrate connecting member.

6. The method according to claim 1, wherein in cross-sectional view, a maximum width of the fourth substrate connecting member is narrower than a maximum width of the third substrate connecting member.

7. The method according to claim 1, wherein a height of the fourth substrate connecting member is higher than a height of the third substrate connecting member.

8. A substrate with an embedded electronic component, comprising:
a first substrate;
a second substrate on which an electronic component is mounted;
a substrate connecting member electrically connecting a first pad of the first substrate and a second pad of the second substrate;
an encapsulating resin filling a gap between the first substrate and the second substrate to cover the electronic component,
wherein the first substrate is disposed opposite the second substrate across the electronic component,
wherein a surface area that is part of the second pad and that is in contact with the substrate connecting member is larger than a surface area that is part of the first pad and in contact with the substrate connecting member, and
wherein the substrate connecting member includes a first section whose width gradually narrows from a surface of the second pad toward a position between the first pad and a center of the substrate connecting member in a height direction in cross-sectional view.

9. The substrate with an embedded electronic component according to claim 8, wherein in a cross-sectional view, the substrate connecting member includes a second section having a constant width between the first pad and the first section.

10. The substrate with an embedded electronic component according to claim 9, wherein as measured from the surface of the second pad, a boundary between the first section and the second section is at a same height as a surface of the electronic component oriented toward the first pad.
